(19) United States
(12) Patent Application Publication
(10) Pub. No.: US 2026/0032873 A1
(43) Pub. Date: Jan. 29, 2026

(54) Cooling Arrangement for an Electric Transaxle

(71) Applicant: Robert Bosch GmbH, Stuttgart (DE)

(72) Inventors: Bopaiah Ittira Biddappa, Farmington Hills, MI (US); Heinz-Bernd Haiser, Ludwigsburg (DE)

(21) Appl. No.: 18/784,529

(22) Filed: Jul. 25, 2024

(51) Int. Cl. H05K 7/20; B60K 11/02

(52) U.S. Cl. CPC H05K 7/20927; B60K 11/02; H05K 7/20872

(57) ABSTRACT

A cooling arrangement for an electric transaxle includes a first coolant path configured to direct coolant to power electronics of the electric transaxle, a proportional valve downstream of the power electronics and configured to selectively proportion the coolant into a first portion directed to a second coolant path and a second portion directed to a third coolant path, and a heat exchanger configured to remove heat from the coolant in the second coolant path. The second and third coolant paths run in parallel to one another and direct the coolant to cool at least one of an electric motor and a transmission of the electric transaxle.

### FIELD

This disclosure relates generally to electric transaxle systems, and, more particularly, to a coolant arrangement for an electric transaxle system.

### BACKGROUND

Conventional electric transaxle systems design includes a cooling system that cools the power electronics and electric motor in series. More specifically, the coolant flows in from the vehicle, through the power electronics, into the electric motor, and then back to the vehicle circuit. In the conventional arrangement, the coolant entering the electric motor therefore has a higher temperature than the coolant entering the power electronics, since that coolant has received heat from the power electronics before entering the electric motor.

Further, the temperature of the coolant is simply a function of the coolant inlet temperature and the temperature increase through the power electronics. At times, the electric motor may overheat, necessitating a reduction in power output, also called power derating, to reduce the temperature of the electric motor. Alternatively, at other times, it may be desirable to increase the temperature of the electric motor and/or gearbox, for example in cold ambient temperatures. What is needed, therefore, are improvements in cooling for electric transaxles that enable heating or cooling the electric motor to a desired temperature.

### SUMMARY

In one embodiment, a cooling arrangement for an electric transaxle comprises a first coolant path configured to direct coolant to power electronics of the electric transaxle, a proportional valve downstream of the power electronics and configured to selectively proportion the coolant into a first portion directed to a second coolant path and a second portion directed to a third coolant path, and a heat exchanger configured to remove heat from the coolant in the second coolant path. The second and third coolant paths run in parallel to one another and direct the coolant to cool at least one of an electric motor and a transmission of the electric transaxle.

In another embodiment, an electric transaxle comprises an electric motor, a transmission operably connected to an output of the electric motor and having an output axle, power electronics configured to supply electrical power to the electric motor, and a cooling arrangement. The cooling arrangement includes a first coolant path configured to direct coolant to the power electronics, a proportional valve downstream of the power electronics and configured to selectively proportion the coolant into a first portion directed to a second coolant path and a second portion directed to a third coolant path, and a heat exchanger configured to remove heat from the coolant in the second coolant path. The second and third coolant paths run in parallel to one another and direct the coolant to cool at least one of an electric motor and a transmission of the electric transaxle.

### BRIEF DESCRIPTION OF THE DRAWINGS

FIG. 1 is a side view of an electric transaxle having a cooling arrangement according to the disclosure.

FIG. 2 is a schematic view of the cooling arrangement of FIG. 1.

FIG. 3 is a schematic view of an exemplary proportional valve of the cooling arrangement of FIG. 1.

FIG. 4 is a process diagram of a method of operating the cooling arrangement of FIG. 1.

FIG. 5 is a schematic view of another cooling arrangement according to the disclosure.

### DETAILED DESCRIPTION

For the purposes of promoting an understanding of the principles of the embodiments described herein, reference is now made to the drawings and descriptions in the following written specification. No limitation to the scope of the subject matter is intended by the references. This disclosure also includes any alterations and modifications to the illustrated embodiments and includes further applications of the principles of the described embodiments as would normally occur to one skilled in the art to which this document pertains.

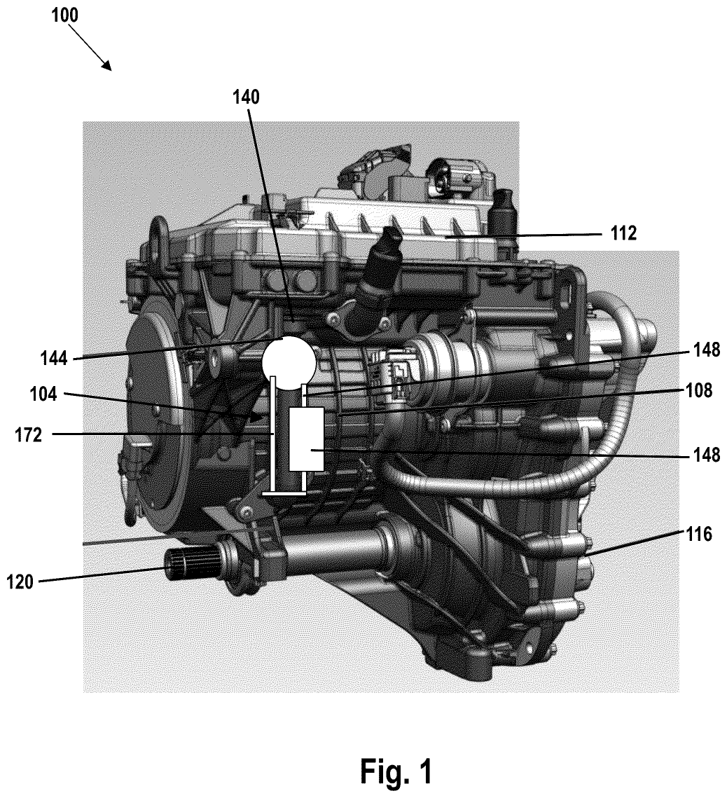

FIG. 1 depicts an electric transaxle system 100 having a cooling arrangement 104 for cooling the components of the electric transaxle system 100. The electric transaxle system 100 also includes an electric motor 108, power electronics 112, and a transmission 116 having an output axle 120 configured to connect to a wheel of a vehicle.

The electric motor 108 is operably connected to the transmission 116 and configured such that the rotational output of the electric motor 108 is received in an input of the transmission 116. The transmission 116 includes a gearing arrangement that reduces the rotational speed of the electric motor output 108 and outputs the reduced speed output to the output axle 120. The output axle 120 outputs the rotational motion from the transmission 116 to a driving mechanism of the vehicle on which the electric transaxle system 100 is installed, for example a wheel, a track, or the like.

The power electronics 112 receive electrical power from the vehicle, for example from the battery of the vehicle, and condition the electrical power to a suitable voltage and current for operating the electric motor 108. Additionally, in some embodiments, the power electronics 112 may include an inverter that converts DC power from the battery to AC power for the electric motor 108.

The components of the power electronics 112, particularly the components responsible for the power conditioning, generate heat during operation. Likewise, the electric motor 108, in particular the windings of the stator and the rotor, generate heat during operation. In order to enable the electric transaxle 100 to operate efficiently, the power electronics 112 and the electric motor 108 are cooled by the cooling arrangement 104.

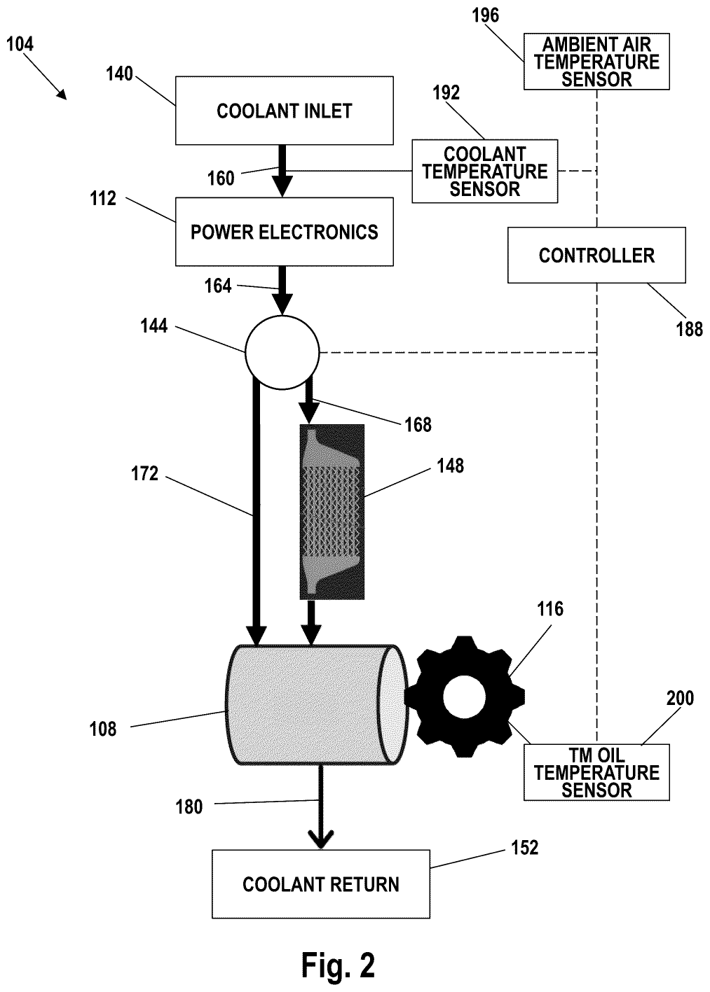

As best seen in FIG. 2, the cooling arrangement includes a coolant inlet 140, a three-way valve 144, a heat exchanger 148, and a coolant return 152. Battery electric vehicles typically include a coolant circuit that provides cooling for the batteries, cabin conditioning, etc. The coolant inlet 140 receives coolant from the vehicle's coolant circuit, and this coolant flows via a coolant path 160 through a coolant pipe running adjacent to or embedded within the power electronics 112. The coolant exiting the power electronics 112 is then routed via a coolant path 164 to the three-way valve 144.

The three-way valve 144 is a three-way proportional valve having an inlet, which receives coolant from the coolant path 164, and two outlets, which direct coolant respectively to the two coolant paths 168, 172 that are arranged in parallel. More specifically, the three-way valve 144 directs a portion of the coolant from the coolant path 164 to the coolant path 168, and the remaining coolant from the coolant path 164 to the coolant path 172. In the illustrated embodiment, the two coolant paths 168, 172 are shown as entering the electric motor 108 independently of one another. The reader should appreciate, however, that the two coolant paths 168 may merge downstream of the heat exchanger 148 and upstream of the electric motor 108.

The heat exchanger 148 is arranged in the coolant path 168 so as to remove heat from the coolant in the coolant path 168. The heat exchanger 148 may be any desired heat exchanger, for example an air-liquid intercooler, a liquid-liquid heat exchanger, a thermoelectric element, a heat pump, or the like.

Operation and control of the various components and functions of the cooling arrangement 104 are performed with the aid of a controller 188. The controller 188 is implemented with general or specialized programmable processors that execute programmed instructions. The instructions and data required to perform the programmed functions are stored in the memory unit associated with the control unit. The processors, the memory, and interface circuitry configure the controller to perform the functions described above and the processes described below. These components can be provided on a printed circuit card or provided as a circuit in an application specific integrated circuit (ASIC). Each of the circuits can be implemented with a separate processor or multiple circuits can be implemented on the same processor. Alternatively, the circuits can be implemented with discrete components or circuits provided in VLSI circuits. Also, the circuits described herein can be implemented with a combination of processors, ASICs, discrete components, or VLSI circuits.

The controller 188 may be integrated in the cooling arrangement 104, or it may be part of the control electronics for the electronic axle 100. In one embodiment, the controller 188 is arranged within or part of the power electronics 112 of the electronic axle 100. In some embodiments, the controller 188 may be remote from the electronic axle 100, for example in the control electronics for the vehicle, and may be connected to the various components of the cooling arrangement 104 via a wired or wireless connection. In some further embodiments, the controller 188 is implemented remote from the vehicle in the “cloud,” and is connected to the vehicle and the cooling arrangement 104 via a wireless data connection.

The controller 188 is operably connected to at least one temperature sensor 192 that senses a temperature of the coolant in the cooling arrangement 104 and to the three-way valve 144. In the illustrated embodiment, the controller 188 is connected to a temperature sensor 192 configured to sense the temperature of the coolant upstream of the power electronics 112, an ambient air temperature sensor 196, and a transmission oil temperature sensor 200. In addition, the controller 188 may be connected to one or more ambient temperature sensors, and/or to the control of the electric motor 108. The controller 188 is configured to operate the three-way valve 144 based on, for example, the temperature sensed by the temperature sensors 192, 196, and 200.

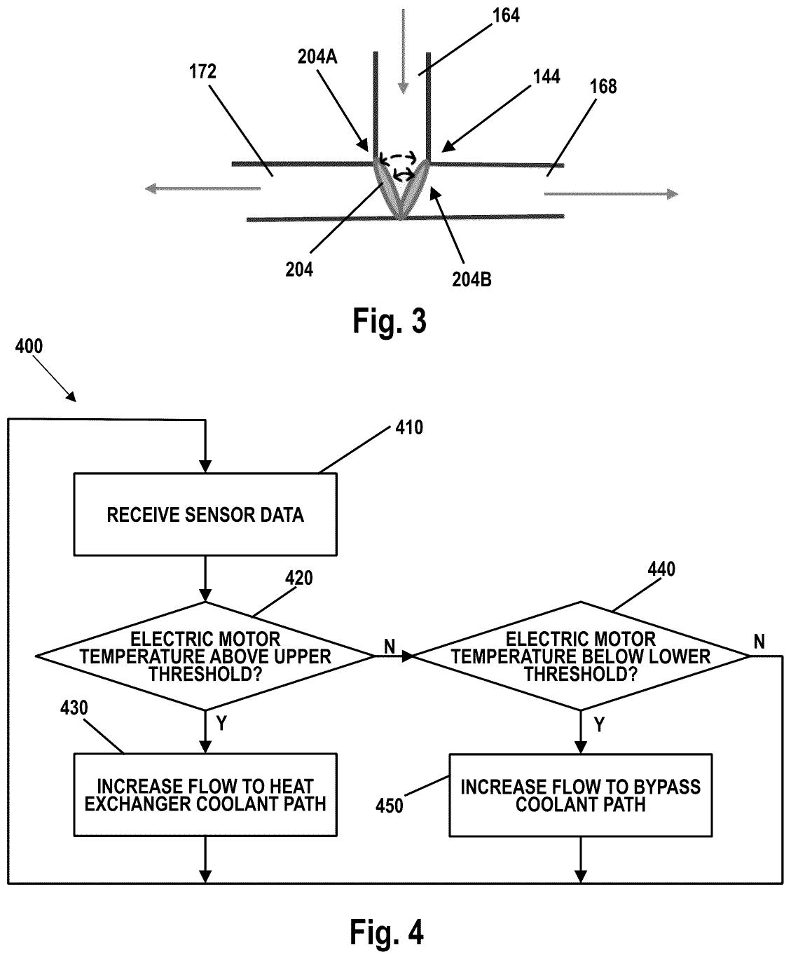

FIG. 3 illustrates a schematic view of the valve 144 and the coolant paths 164, 168, 172. In the embodiment illustrated in FIG. 3, the valve 144 includes a valve member 204 that splits the flow from the coolant path 164 of the coolant exiting the power electronics 112 into the two parallel coolant paths 168, 172. In particular, in the illustrated embodiment, the valve 144 is a flap valve in which the valve member 204 is a flap. In other embodiments, the valve member 144 may be a disk, ball, cylinder, plug, gate, or other suitable valve member.

As shown in FIG. 3, the valve member 204 has two end positions 204A and 204B. At end position 204A, the valve member 204 directs all flow to the coolant path 172 that bypasses the heat exchanger 148, also referred to as the bypass coolant path, and blocks any flow to the coolant path 168 that leads to the heat exchanger 148, also referred to as the heat exchanger coolant path. Conversely, at position 204B, the valve member 204 blocks any flow to the bypass coolant path 172 and directs all flow to the heat exchanger coolant path 168. Additionally, since the valve 144 is a proportional valve, the valve member 204 also has a plurality, or in some instances an infinite number (i.e. the valve is a continuously variable valve), of intermediate positions between the two end positions 204A, 204B. As such, the valve 144 is designed to control the proportion of coolant that flows through the heat exchanger 148 at any given time based on the position of the valve member 204.

FIG. 4 illustrates a process 400 for controlling the valve 144. The process 400 may be executed by the controller 188 to operate the valve 144 based on inputs from, for example, the temperature sensor 192 upstream of the power electronics 112, operating characteristics of the electric motor 108, and/or one or more additional temperature sensors such as, for example, an ambient temperature sensor, an electric motor temperature sensor, a temperature sensor downstream of the power electronics 112 and upstream of the valve 144, a temperature sensor downstream of the electric motor 108, and the like.

The process begins with the controller 188 receiving sensor data (block 400). The sensor data may include, for example, sensor data directly indicative of the temperature of the electric motor 108 from, for example, a temperature sensor that senses the temperature of the coolant in the electric motor 108 or of the temperature of one or more other components of the electric motor 112 or transmission 116. Alternatively, the sensor data may include information that indirectly relates to the temperature of the electric motor 108. For example, the sensor data may include the temperature of the coolant upstream of the power electronics 112, as sensed by the coolant temperature sensor 192, the ambient air temperature, as sensed by the ambient air temperature sensor 196, and the transmission oil temperature, as sensed by the transmission oil temperature sensor 200.

The method 400 proceeds with determining whether the electric motor temperature is above an upper threshold (block 420) and, if so, increasing the proportion of flow to the heat exchanger coolant path 168 (block 430). Alternatively, if the electric motor temperature is below a lower threshold (block 440), the controller 188 operates to increase flow to the bypass coolant path 172 (block 450). If the coolant is neither above the upper threshold in block 420 or below the lower threshold in block 440, the valve position is not adjusted.

In particular, the comparison of the electric motor temperature to the threshold temperatures may occur indirectly, i.e. not based on a sensed temperature of the motor itself. For instance, the controller 188 may include, stored in non-transitory memory, one or more tables or functions that correlate the sensed values to the electric motor temperature. In one embodiment, the sensor data from the coolant temperature sensor 192 and the ambient temperature sensor 196, present a known correlation to the electric motor temperature and the cooling needed to maintain the electric motor within the desired temperature range. In other embodiments, additional sensors may be used, for example a transmission oil temperature sensor 200.

The temperature of the electric motor is primarily a function of the operating power of the electric motor 108, the ambient temperature, and the temperature and quantity of coolant flowing through the electric motor 108. In a given system, the power electronics 112 are known to cause an increase in the temperature of the coolant flowing through the power electronics 112 that is based on the ambient temperature, and therefore the temperature of the coolant exiting the power electronics 112 can be modeled based on the ambient temperature. In some embodiments, this modeling may be performed with a coolant temperature sensor downstream of the power electronics 112 so as to calibrate the model based on the parameters of the given system.

Similarly, the coolant temperature reduction as a result of the heat exchanger 148 is known based on the ambient air temperature and the quantity of coolant directed through the heat exchanger 148. Thus, the temperature of the electric motor 108 can be modeled as a function of data sensed from the coolant temperature sensor 192, the ambient air temperature 196, and the power draw or power output of the electric motor 108.

As such, the memory of the controller 188 includes a model that correlates the temperature of the electric motor 108 to the temperatures sensed by the coolant temperature sensor 192, the ambient air temperature sensor 196, the transmission oil temperature sensor 200, and the operating parameters of the electric motor 108.

Thus, based on these input variables, the controller 188 determines whether the temperature of the electric motor 108 should be increased, i.e. is below a lower threshold, for example in cold ambient temperatures and when the motor has not yet warmed up. The controller 188 then operates the valve 144 to direct more or all of the coolant to the bypass coolant path 172 such that the coolant heated by the power electronics 164 flows into the electric motor 108. This allows the controller 188 to facilitate warming the electric motor 108 to an efficient operating temperature when starting up the electric motor 108 and/or in cold ambient temperatures.

Alternatively, if the temperature of the electric motor 108 should be decreased, i.e. is above an upper threshold, the controller 188 operates the valve 144 to direct more of all of the coolant to the heat exchanger coolant path 168 such that the coolant to the electric motor 108 provides improved cooling. As such, the electric motor 108 can be maintained within the desired operating temperature range in warmer ambient temperatures and over during high power operations.

In various embodiments, the cooling arrangement 104 or the vehicle on which the electric transaxle 100 is installed may be further configured to adjust the coolant flow to the inlet 140 of the cooling arrangement 104. As a result, combined with the adjustment of the position of the valve member 204 of the valve 144, the cooling arrangement 104 enables improved cooling for both the power electronics 112 and the electric motor 108.

In some embodiments, the determination of whether the electric motor is above or below the respective upper or lower thresholds (blocks 420 and 440) is based not on the current temperature, but a predicted temperature of the electric motor 108 and/or on an upper or lower threshold that varies based on other predicted variables. For example, in one embodiment, the controller 188 is connected to a data source, for example GPS data, via, for example, a wireless or cellular connection, that identifies that the vehicle will soon be climbing a hill, requiring increased power draw from the electric motor 108. In response, the controller 188 identifies the electric motor predicted temperature as rising above the upper threshold in block 420, and operates the valve 144 to increase the flow to the heat exchanger coolant path 168. Additionally or alternatively, the controller 188 may be configured to lower the upper threshold, which then causes the controller 188 to operate the valve 144 to increase the flow to the heat exchanger coolant path 168 so as to reduce the temperature of the electric motor 108 in anticipation of the added power draw on the electric motor 108.

In addition, because the cooling of the electric motor 108 is improved by the disclosed cooling arrangement 104, the electric motor 108 may be reduced in capacity and therefore size. As an initial matter, the electric motor 108 does not require an expensive oil cooled arrangement that would increase both cost and size of the electric motor 108, since the cooling arrangement 104 provides sufficient cooling with the coolant from the vehicle. Further, because the cooling arrangement 104 provides improved cooling, the electric motor 108 is less likely to overheat, which results in reduced power output to prevent damage to the electric motor 108. As a result, since the electric motor 108 is less likely to require reduced power output operation, the electric motor 108 can have lower maximum power output capacity than conventional electric transaxles, further reducing the cost of the electric transaxle 100.

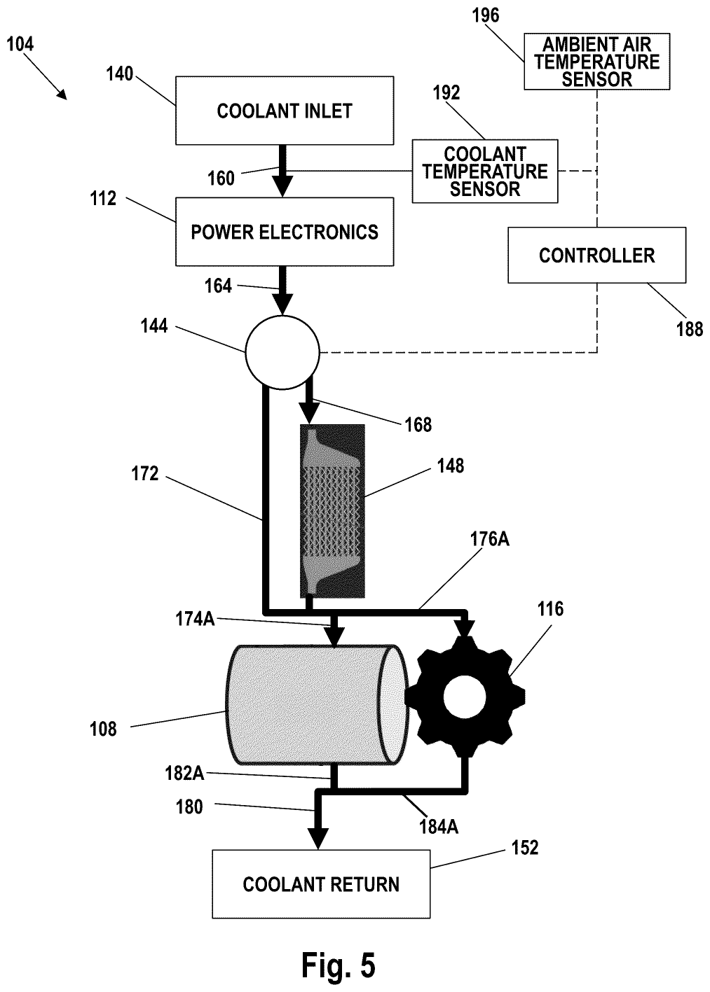

FIG. 5 illustrates another embodiment of a cooling system 104A for an electric transaxle 100. The cooling system 104A is essentially the same as the cooling system 104 described above, except that downstream of the heat exchanger 148, the coolant flow paths 168, 172 merge and then split again into two parallel paths, one coolant flow path 174A delivering coolant to the electric motor 108 and the other coolant flow path 176A delivering coolant to the transmission 116. The coolant paths 182A and 184A downstream of the electric motor 108 and transmission 116, respectively, join to deliver the coolant to the coolant return 152 to return the coolant to the vehicle. Thus, in the embodiment of FIG. 5, the transmission 116 is cooled directly via the coolant flow passing through the heat exchanger 148 and the coolant bypass line 172.

It will be appreciated that variants of the above-described and other features and functions, or alternatives thereof, may be desirably combined into many other different systems, applications or methods. Various presently unforeseen or unanticipated alternatives, modifications, variations or improvements may be subsequently made by those skilled in the art that are also intended to be encompassed by the foregoing disclosure.

What is claimed is:

1. A cooling arrangement for an electric transaxle comprising:
a first coolant path configured to direct coolant to power electronics of the electric transaxle;
a proportional valve downstream of the power electronics and configured to selectively proportion the coolant into a first portion directed to a second coolant path and a second portion directed to a third coolant path; and
a heat exchanger configured to remove heat from the coolant in the second coolant path,
wherein the second and third coolant paths run in parallel to one another and direct the coolant to cool at least one of an electric motor and a transmission of the electric transaxle.

2. The cooling arrangement of claim 1 further comprising:
a coolant temperature sensor configured to sense a first temperature of the coolant upstream of the power electronics; and
a controller configured to receive sensor data from the coolant temperature sensor and to operate the proportional valve to proportion the coolant based on at least the sensed first temperature.

3. The cooling arrangement of claim 2, further comprising:
an ambient air temperature sensor configured to sense an ambient air temperature,
wherein the controller is further configured to receive sensor data from the ambient air temperature sensor and to operate the proportional valve to proportion the coolant further based on the sensed ambient air temperature.

4. The cooling arrangement of claim 3, wherein the controller is further configured to operate the proportional valve to proportion the coolant further based on at least one of a power draw and a power output of the electric motor.

5. The cooling arrangement of claim 4, wherein the at least one of the power draw and the power output of the electric motor is at least one of a predicted future power draw or a predicted future power output.

6. The cooling arrangement of claim 1, wherein the second and third coolant paths direct the coolant to a housing of the electric motor so as to cool the electric motor.

7. The cooling arrangement of claim 1, further comprising:
a coolant inlet configured to receive coolant from a vehicle on which the electric transaxle is arranged; and
a coolant return arranged downstream of the electric motor and configured to return the coolant to the vehicle.

8. The cooling arrangement of claim 1, wherein the heat exchanger is configured as an air-liquid intercooler.

9. The cooling arrangement of claim 1, wherein the proportional valve is configured as a continuously variable valve.

10. The cooling arrangement of claim 1, wherein the second and third coolant paths join into a common coolant path upstream of the at least one of the electric motor and transmission.

11. An electric transaxle comprising:
an electric motor;
a transmission operably connected to an output of the electric motor and having an output axle;
power electronics configured to supply electrical power to the electric motor; and
a cooling arrangement comprising:
a first coolant path configured to direct coolant to the power electronics;
a proportional valve downstream of the power electronics and configured to selectively proportion the coolant into a first portion directed to a second coolant path and a second portion directed to a third coolant path; and
a heat exchanger configured to remove heat from the coolant in the second coolant path,
wherein the second and third coolant paths run in parallel to one another and direct the coolant to cool at least one of the electric motor and transmission.

12. The electric transaxle of claim 11, wherein the cooling arrangement further comprises:
a coolant temperature sensor configured to sense a first temperature of the coolant upstream of the power electronics; and
a controller configured to receive sensor data from the coolant temperature sensor and to operate the proportional valve to proportion the coolant based on at least the sensed first temperature.

13. The electric transaxle of claim 12, further comprising:
an ambient air temperature sensor configured to sense an ambient air temperature,
wherein the controller is further configured to receive sensor data from the ambient air temperature sensor and to operate the proportional valve to proportion the coolant further based on the sensed ambient air temperature.

14. The electric transaxle of claim 13, wherein the controller is further configured to operate the proportional valve to proportion the coolant further based on at least one of a power draw and a power output of the electric motor.

15. The electric transaxle of claim 14, wherein the at least one of the power draw and the power output of the electric motor is at least one of a predicted future power draw or a predicted future power output.

16. The electric transaxle of claim 11, wherein the second and third coolant paths direct the coolant into a housing of the electric motor so as to cool the electric motor.

17. The electric transaxle of claim 11, further comprising:
a coolant inlet configured to receive coolant from a vehicle on which the electric transaxle is arranged; and
a coolant return arranged downstream of the electric motor and configured to return the coolant to the vehicle.

18. The electric transaxle of claim 11, wherein the heat exchanger is configured as an air-liquid intercooler.

19. The electric transaxle of claim 11, wherein the proportional valve is configured as a continuously variable valve.

20. The electric transaxle of claim 11, wherein the second and third coolant paths join into a common coolant path upstream of the at least one of the electric motor and transmission.
